(19) United States
(12) Patent Application Publication
(10) Pub. No.: US 2016/0334456 A1
(43) Pub. Date: Nov. 17, 2016

(54) Method of generating a curve to determine an optimal operation of a wafer

(71) Applicant: United Microelectronics Corp., Hsin-Chu City (TW)

(72) Inventors: Ya-Ching Cheng, Hsinchu City (TW); Chun-Liang Hou, Hsinchu County (TW); Hsiao-Kwang Yang, Hsinchu County (TW); Chien-Jung Su, Hsinchu County (TW); Guan-Lin Chen, New Taipei City (TW)

(21) Appl. No.: 14/708,300

(22) Filed: May 11, 2015

(51) Int. Cl. G01R 31/26; G11C 29/08

(52) U.S. Cl. CPC G01R 31/2601; G11C 29/08

(57) ABSTRACT

The fail bit count data, shmoo data, static noise margins and write margins corresponding to a wafer are measured. Using the above mentioned measurements, variables used to generate the curve are calculated. The variables used to generate the curve include the standard deviation of the fail bit count data, the static noise margins and the write margins. The curve is used to determine optimal operating condition of a fabrication process.

### BACKGROUND OF THE INVENTION

1. Field of the Invention

The present invention presents a method of generating a curve to determine an optimal operation of a wafer, more particularly, a method of generating a curve to determine an optimal static noise margin and an optimal supply voltage of a wafer.

2. Description of the Prior Art

Advancement in technology has resulted to fabrication processes that are able to produce smaller electronic devices. These electronic devices are able to operate with reduced operating voltage. To produce smaller electronic devices, the size of the transistors is reduced. The sensitivity of the electronic devices to noise is also increased. Thus, there is a need to determine an optimal static noise margin and an optimal supply voltage of a fabrication process.

For the prior art, to determine an optimal static noise margin and an optimal supply voltage of a fabrication process, a plurality of wafers fabricated using the same fabrication process having different static noise margins are measured for corresponding optimal supply voltages. FIG. 1 illustrates a graph 100 showing a smile curve according to prior art. The different static noise margins and corresponding optimal supply voltages of the wafers are used to plot the graph. From the graph, the smile curve is generated using the data points 101, each corresponding to a wafer plotted on the graph. The line 102 on right side of the smile curve represents write fail dominating wafers and the line 103 on the left side of the smile curve represents read fail dominating wafers. The point 104 where the two lines 102 and 103 meet represents the minimum supply voltage for optimal operation of the fabrication process.

### SUMMARY OF THE INVENTION

An embodiment of the present invention presents a method for generating a curve. The method comprises measuring fail bit count data and shmoo data of a die of a wafer and static noise margins and write margins of a plurality of dies of the wafer, determining a read shift ratio and a write shift ratio according to the shmoo data, calculating a read shift constant according to the static noise margins and the fail bit count data corresponding to a certain supply voltage of a peripheral circuit, calculating a write shift constant according to the write margins and the fail bit count data corresponding to a certain supply voltage of a memory cell, determining a read slope according to the read shift constant and the read shift ratio, determining a write slope according to the write shift constant and the write shift ratio, and determining the curve of the wafer according to the read slope and the write slope.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a graph showing a smile curve according to prior art.

FIG. 2 illustrates a flowchart of a method of generating a curve according to an embodiment of the present invention.

FIG. 3 illustrates an example of a shmoo plot according to an embodiment of the present invention.

FIG. 4 illustrates another example of a shmoo plot according to an embodiment of the present invention.

FIG. 5 illustrates a plot of a normal distribution of the static noise margins according to an embodiment of the present invention.

FIG. 6 illustrates a plot of a normal distribution of the supply voltage of a memory cell according to an embodiment of the present invention.

FIG. 7 illustrates a plot of a normal distribution of the write margins according to an embodiment of the present invention.

FIG. 8 illustrates a plot of a normal distribution of the supply voltage of a peripheral circuit according to an embodiment of the present invention.

FIG. 9 illustrates a curve according to an embodiment of the present invention.

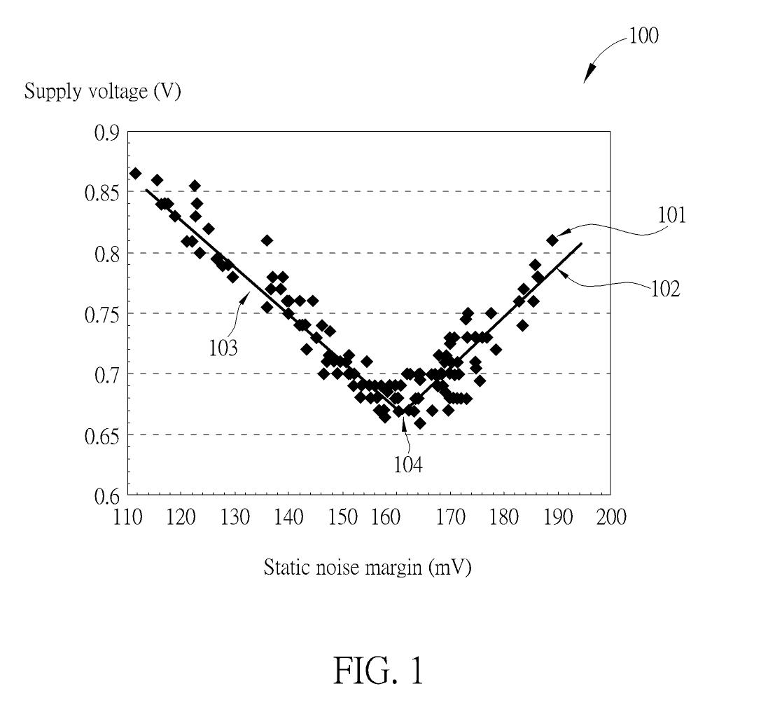

### DETAILED DESCRIPTION

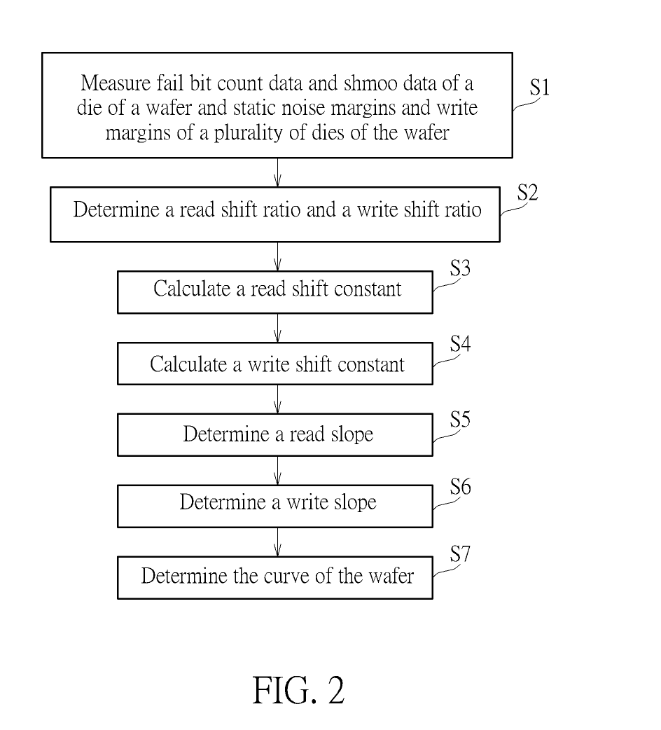

FIG. 2 illustrates a flowchart of a method of generating a curve according to an embodiment of the present invention. The method may include, but is not limited, to the following steps:

Step S1: measure fail bit count data and shmoo data of a die of a wafer and static noise margins and write margins of a plurality of dies of the wafer;

Step S2: determine a read shift ratio and a write shift ratio according to the shmoo data;

Step S3: calculate a read shift constant according to the static noise margins and the fail bit count data corresponding to a certain supply voltage of a peripheral circuit;

Step S4: calculate a write shift constant according to the write margins and the fail bit count data corresponding to a certain supply voltage of a memory cell;

Step S5: determine a read slope according to the read shift constant and the read shift ratio;

Step S6: determine a write slope according to the write shift constant and the write shift ratio; and

Step S7: determine the curve of the wafer according to the read slope and the write slope.

In step S1, the fail bit count data and the shmoo data may be measured from a die of a wafer. And, static noise margins and write margins may be measured from a plurality of dies of the wafer. The above mentioned measurements may be measurements from dies of a single wafer. The fail bit count data and the shmoo data may be generated according to a varying supply voltage of a peripheral circuit of the die and a varying supply voltage of a memory cell of the die. The shmoo data may be generated when the die operates without failed bits at certain combinations of the supply voltages of the peripheral voltage and the supply voltages of the memory cell. The fail bit count data corresponds to the number of bits in the memory cell that fail at certain combinations of the supply voltages of the peripheral voltage and the supply voltages of the memory cell.

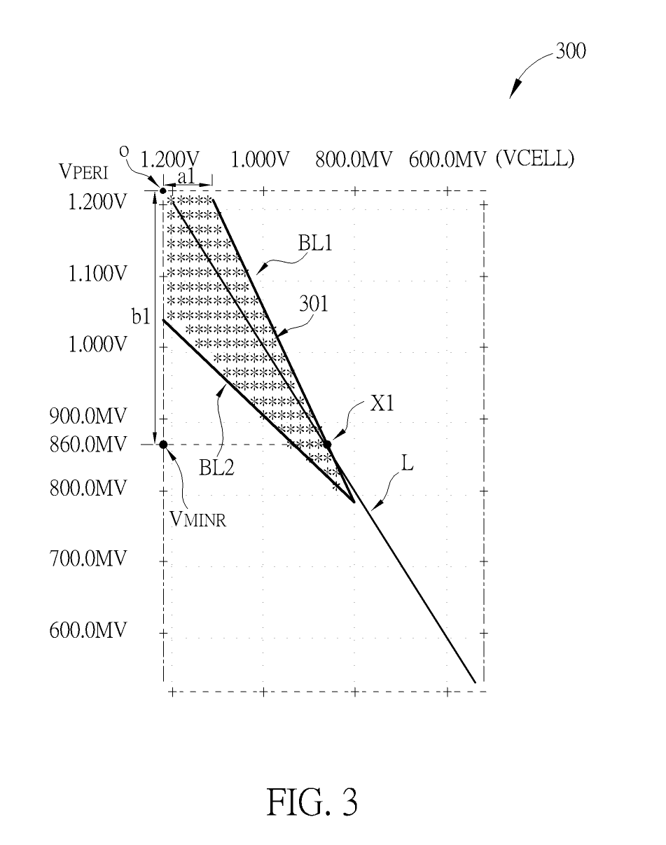

FIG. 3 illustrates an example of a shmoo plot 300 according to an embodiment of the present invention. The shmoo plot may or may not be generated and/or used during the method of generating the curve. The shmoo plot in FIG. 3 maybe used as a supplement in the description of the present invention. Although, generating of the shmoo plot may not be necessary to complete the method of generating the curve, the shmoo plot 300 may be used to show the shmoo data mentioned in step S1. Each die of the wafer may have a corresponding shmoo plot. The shmoo plot 300 may comprise of shmoo data 301. The shmoo data 301 measured in step S1 may correspond to a minimum number of shmoo data 301 measured from the die to generate a first boundary BL1 and a second boundary BL2 of the shmoo plot 300. Or, in some other embodiment, the shmoo data 301 may comprise of the complete set of shmoo data measured from the die.

In step S2, the read shift ratio (b/a)_{R} and the write shift ratio (b/a)_{W} may be determined according to the shmoo data 301. The read shift ratio (b/a)_{R} is generated by determining a minimum supply voltage V_{MINR} for a read operation according to the first boundary BL1 formed by the shmoo data 301 as shown in FIG. 3. The minimum supply voltage V_{MINR} for the read operation is determined by identifying an intersecting point X1 between the first boundary BL1 and a diagonal line L. The diagonal line L is generated according to a relation between the supply voltage V_{CELL} of the memory cell and the supply voltage V_{PERI} of the peripheral circuit. A ratio of the supply voltage V_{CELL} of the memory cell and the supply voltage V_{PERI} of the peripheral circuit to generate each point on the diagonal line L is 1. This means that the value of the supply voltage V_{CELL} of the memory cell may be the same as the supply voltage V_{PERI} of the peripheral circuit. A first width b1 may be determined to be a width going from an origin point O of the shmoo data 301 to a supply voltage V_{PERI} of the peripheral circuit across the minimum supply voltage V_{MINR} for the read operation. A second width a1 may be determined to be a width going from the origin point O to a supply voltage V_{CELL} of the memory cell where the first boundary BL1 starts. The read shift ratio (b/a)_{R} may then be calculated according to a ratio of the first width b1 and the second width a1 in FIG. 3.

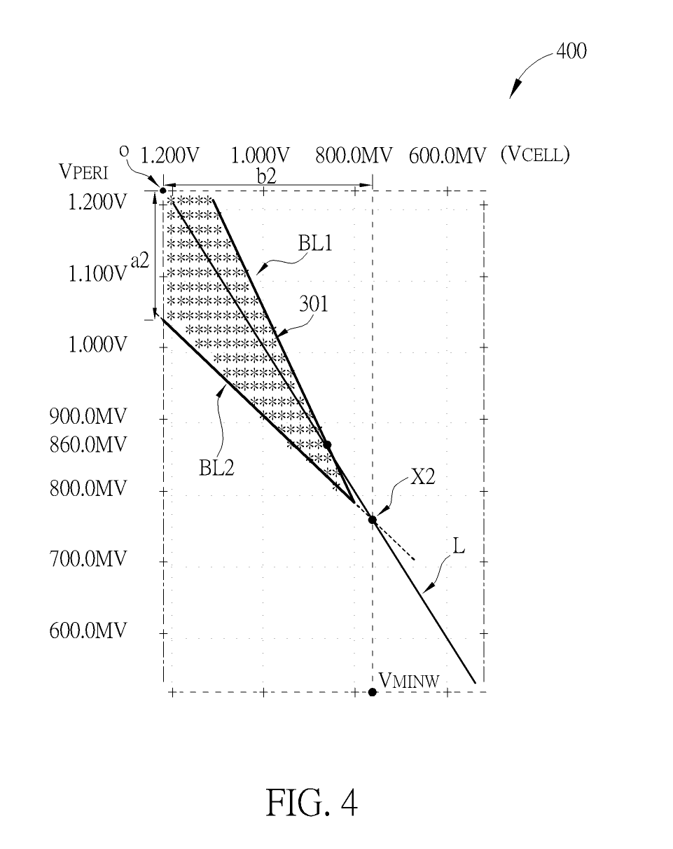

To describe the method of determining the write shift ratio (b/a)_{W}, FIG. 4 is used as a supplement for the description of the present invention. FIG. 4 illustrates another example of a shmoo plot 400 according to an embodiment of the present invention. FIG. 3 and FIG. 4 may illustrate the same shmoo plot. The write shift ratio (b/a)_{W} may be generated by determining a minimum supply voltage V_{MINW} for a write operation according to a second boundary BL2 formed by the shmoo data 301 as shown in FIG. 4. The minimum supply voltage V_{MINW} for the write operation determined according to the second boundary BL2 is determined by identifying an intersecting point X2 between the second boundary BL2 and the diagonal line L. The diagonal line L is generated according to a relation between the supply voltage V_{CELL} of the memory cell and the supply voltage V_{PERI} of the peripheral circuit. A ratio of the supply voltage V_{CELL} of the memory cell and the supply voltage V_{PERI} of the peripheral circuit to generate each point on the diagonal line L is 1. This means that the value of the supply voltage V_{CELL} of the memory cell may be the same as the supply voltage V_{PERI} of the peripheral circuit. A first width b2 may be determined to be a width going from an origin point O of the shmoo data 301 to the supply voltage V_{CELL} of the memory cell across the minimum supply voltage V_{MINW} for the write operation. A second width a2 may be determined to be a width going from the origin point O to a supply voltage V_{PERI} of the peripheral circuit where the second boundary BL2 starts. The write shift ratio (b/a)_{W} may be calculated according to a ratio of the first width b2 and the second width a2 in FIG. 4.

When the static noise margin of a die is shifted by N millivolts, a first boundary BL1 may be shifted by N millivolts multiplied by the read shift constant m_{R}(N*m_{R} mV). And accordingly, the minimum supply voltage V_{MINR} for the read operation of the wafer may be shifted by N millivolts multiplied by the read shift constant m_{R} and then multiplied by the read shift ratio (b/a)_{R} (N*m_{R}*(b/a)_{R} mV). Thus, the read shift constant m_{R} may be determined and used in the determination of a read slope.

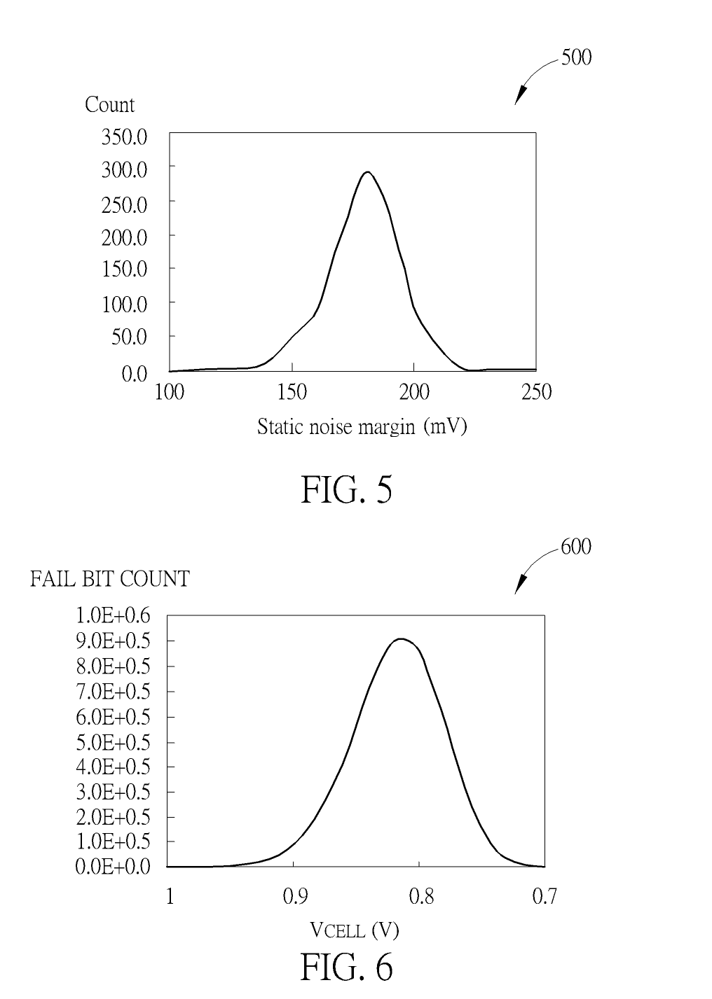

In step S3, the read shift constant m_{R} may be calculated according to the static noise margins and the fail bit count data corresponding to a varying supply voltage V_{CELL} of a memory cell at a certain supply voltage V_{PERI} of a peripheral circuit. The method of calculating for the read shift constant m_{R} may comprise calculating a standard deviation σ_{SNM} of the static noise margins. FIG. 5 illustrates a plot 500 of a normal distribution of the static noise margins according to an embodiment of the present invention. The plot in FIG. 5 may be used to determine the standard deviation σ_{SNM} of the static noise margins. Each of the plurality of dies of the wafer may be measured for a corresponding static noise margin. The static noise margins measured from the plurality of dies of the wafer are used to generate the plot in FIG. 5. The plot is generated according to the static noise margin in correspondence to the count of dies having the value of static noise margin. A standard deviation V_{SR} of the fail bit count data corresponding to a varying supply voltage V_{CELL} of the memory cell at the certain supply voltage V_{PERI} of the peripheral circuit may be calculated. FIG. 6 illustrates a plot 600 of a normal distribution of the supply voltage of a memory cell according to an embodiment of the present invention. The fail bit count data measured from the plurality of dies of the wafer are used to generate the plot in FIG. 6. The plot in FIG. 6 is generated according to the fail bit count data in correspondence with the varying supply voltage V_{CELL} of the memory cell. Each of the plurality of dies may have a corresponding standard deviation V_{SR} of the fail bit count data. To have an accurate standard deviation V_{SR} of the fail bit count data for a wafer, the standard deviation V_{SR} of the fail bit count data of a plurality of dies of a wafer may be averaged and be used as the standard deviation V_{SR} of the fail bit count data in the following steps for generating the curve. The read shift constant m_{R} may then be determined according to the standard deviation σ_{SNM} of the static noise margins and the standard deviation V_{SR} of the fail bit count data. To determine the read shift constant m_{R}, the following equation (1) may be used:

m_{R}=V_{SR}/σ_{SNM} (1)

where:
V_{SR} is the standard deviation of the fail bit count data of the die of a wafer corresponding to a varying supply voltage V_{CELL} of the memory cell at the certain supply voltage V_{PERI} of the peripheral circuit; and
σ_{SNM} is the standard deviation of the static noise margins.

When the write margin of a die is shifted by M millivolts, a second boundary BL2 may be shifted by M millivolts multiplied by the write shift constant m_{W} (M*m_{W} mV). And accordingly, the minimum supply voltage V_{MINW} for the write operation of the wafer may be shifted by M millivolts multiplied by the write shift constant m_{W} and then multiplied by the write shift ratio (b/a)_{W} (M*m_{W}*(b/a)_{W} mV). Thus, the write shift constant m_{W} may be determined and used in the determination of a write slope.

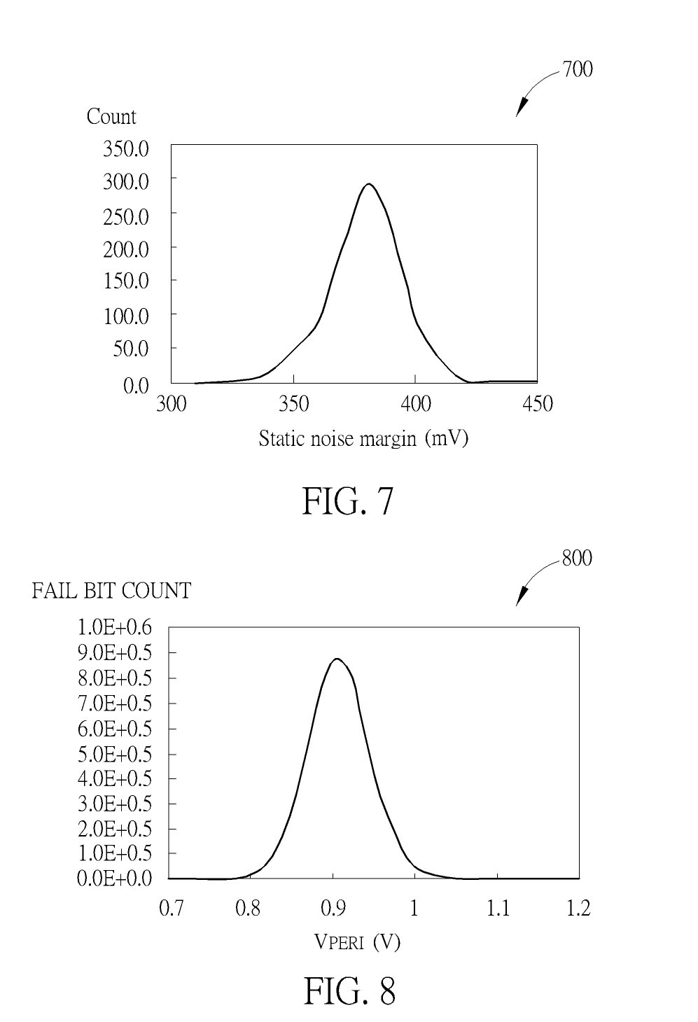

In step S4, the write shift constant m_{W} may be calculated according to the write margins and the fail bit count data corresponding to a certain supply voltage of a memory cell. The method of calculating for the write shift constant m_{W} may comprise calculating a standard deviation of the write margins. FIG. 7 illustrates a plot 700 of a normal distribution of the write margins according to an embodiment of the present invention. The plot in FIG. 7 may be used to determine the standard deviation σ_{WRM} of the write margins. Each die of the wafer may be measured for a corresponding write margin. The write margins measured from the plurality of dies of the wafer are used to generate the plot in FIG. 7. The plot in FIG. 7 is generated using the write margins in correspondence to the count of dies having the same value for write margin. A standard deviation V_{SW} of the fail bit count data corresponding to a varying supply voltage V_{CELL} of the memory cell at the certain supply voltage V_{PERI} of the peripheral circuit may be calculated. FIG. 8 illustrates a plot 800 of a normal distribution of the supply voltage of a peripheral circuit according to an embodiment of the present invention. The fail bit count data measured from the plurality of dies of the wafer are used to generate the plot in FIG. 8. The plot in FIG. 8 is generated using the fail bit count data measured from the plurality of dies in correspondence to the varying supply voltage V_{PERI} of the peripheral circuit. Each of the plurality of dies may have a corresponding standard deviation V_{SW} of the fail bit count data. To have a more accurate standard deviation V_{SW} of the fail bit count data for the wafer, the standard deviation V_{SW} of the fail bit count data of the plurality of dies of a wafer may be averaged and be used as the standard deviation V_{SW} of the fail bit count data in the following steps. The write shift constant m_{W} may be determined according to the standard deviation σ_{WRM} of the write margins and the standard deviation V_{SW} of the fail bit count data. To determine the write shift constant m_{W}, the following equation (2) may be used:

m_{W}=V_{SW}/σ_{WRM} (2)

where:
V_{SW} is the standard deviation of the fail bit count data of the die of the wafer corresponding to a varying supply voltage V_{PERI} of the peripheral circuit at the certain supply voltage V_{CELL} of the memory cell; and
σ_{WRM} is the standard deviation of the write margins.

In step S5, the read slope may be determined according to the read shift constant m_{R} and the read shift ratio (b/a)_{R}. The read shift constant m_{R} may be determined using equation (1). To determine the read slope, the following equation (3) may be used:

Read slope=V_{SR}/σ_{SNM}*(b/a)_{R}*(−1) (3)

where:
(b/a)_{R} is the read shift ratio;
V_{SR} is the standard deviation of the fail bit count data of a plurality of die of a wafer corresponding to a varying supply voltage V_{CELL} of the memory cell at the certain supply voltage V_{PERI} of the peripheral circuit; and
σ_{SNM} is the standard deviation of the static noise margins.

In step S6, the write slope may be determined according to the write shift constant m_{W} and the write shift ratio (b/a)_{W}. The write shift constant m_{W} may be determined using equation (2). To determine the write slope, the following equation (4) may be used:

Write slope=V_{SW}/σ_{WRM}*(b/a)_{W}*(−b₁(WRM,SNM)) (4)

where:
(b/a)_{W} is the write shift ratio;
V_{SW} is the standard deviation of the fail bit count data of a plurality of die of the wafer corresponding to a varying supply voltage V_{PERI} of the peripheral circuit at the certain supply voltage V_{CELL} of the memory cell;
σ_{WRM} is the standard deviation of the write margins; and
b₁(WRM,SNM) is the slope of the write margin over the static noise margin.

Note that the read slope and the write slope are independent from each other.

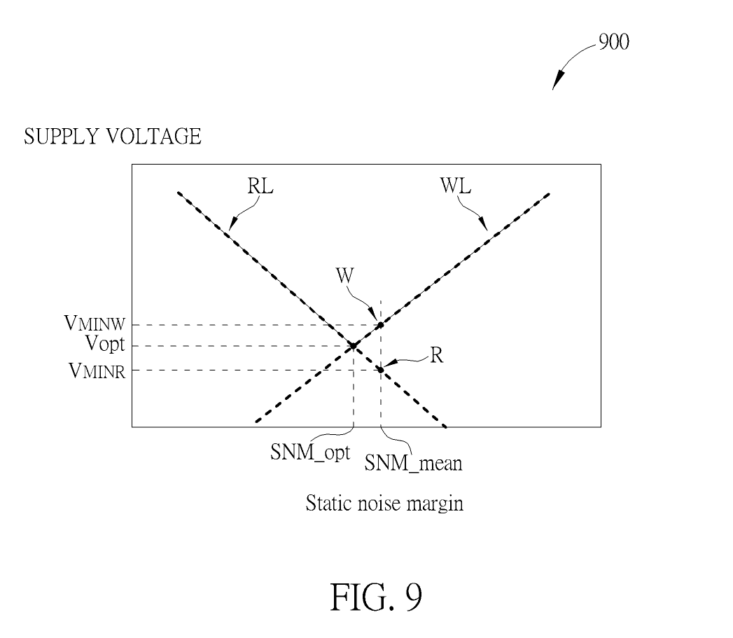

In step S7, the curve of the wafer may be determined according to the read slope and the write slope. In the present invention, the curve may be generated using a single wafer. And the curve generated may be a smile curve. To further elaborate on the method of determining the curve, FIG. 9 may be used in correspondence with the detailed description. FIG. 9 illustrates a curve 900 according to an embodiment of the present invention. The method of determining the curve may comprise determining a static noise margin mean SNM_mean of the wafer according to the static noise margins in FIG. 9. A minimum supply voltage V_{MINW} for a write operation of the wafer in FIG. 9 may be determined according to the shmoo data. A minimum supply voltage V_{MINR} for a read operation of the wafer in FIG. 9 may be determined according to the shmoo data. The minimum supply voltage for the write operation corresponding to the static noise margin mean SNM_mean may be plotted on a graph shown as point W in FIG. 9. The minimum supply voltage for the read operation corresponding to the static noise margin mean may be plotted on the graph shown as point R in FIG. 9. A write line WL on the graph in FIG. 9 crossing the point W corresponding to the minimum supply voltage V_{MINW} for the write operation may be plotted according to the write slope. A read line RL on the graph in FIG. 9 crossing the point R corresponding to the minimum supply voltage V_{MINR} for the read operation may be plotted according to the read slope. Furthermore, from the curve, an optimal static noise margin SNM_OPT and an optimal supply voltage V_{OPT} of a wafer of the wafer according to an intersecting point of the write line WL and the read line RL may be determined.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for generating a curve, comprising:
measuring fail bit count data and shmoo data of a die of a wafer and static noise margins and write margins of a plurality of dies of the wafer;
determining a read shift ratio and a write shift ratio according to the shmoo data;
calculating a read shift constant according to the static noise margins and the fail bit count data corresponding to a certain supply voltage of a peripheral circuit;
calculating a write shift constant according to the write margins and the fail bit count data corresponding to a certain supply voltage of a memory cell;
determining a read slope according to the read shift constant and the read shift ratio;
determining a write slope according to the write shift constant and the write shift ratio; and
determining the curve of the wafer according to the read slope and the write slope.

2. The method of claim 1, wherein the fail bit count data and the shmoo data are generated according to a varying supply voltage of a peripheral circuit of the die and a varying supply voltage of a memory cell of the die.

3. The method of claim 1, wherein calculating the read shift constant according to the static noise margins and the fail bit count data corresponding to the certain supply voltage of the peripheral circuit comprises:
calculating a standard deviation of the static noise margins;
calculating a standard deviation of the fail bit count data corresponding to a varying supply voltage of the memory cell at the certain supply voltage of the peripheral circuit; and
determining the read shift constant according to the standard deviation of the static noise margins and the standard deviation of the fail bit count data.

4. The method of claim 1, wherein determining the read shift ratio according to the shmoo data comprises:
determining a minimum supply voltage for a read operation according to a first boundary formed by the shmoo data;
determining a first width from an origin point of the shmoo data to a supply voltage of the peripheral circuit across the minimum supply voltage for the read operation;
determining a second width from the origin point to a supply voltage of the memory cell where the first boundary starts; and
calculating the read shift ratio according to a ratio of the first width and the second width.

5. The method of claim 4, wherein determining the minimum supply voltage for the read operation according to the first boundary is determining an intersecting point between the first boundary and a diagonal line corresponding to the supply voltage of the memory cell and the supply voltage of the peripheral circuit.

6. The method of claim 5, wherein a ratio of the supply voltage of the memory cell and the supply voltage of the peripheral circuit corresponding to each point on the diagonal line is 1.

7. The method of claim 1, wherein calculating the write shift constant according to the write margins and the fail bit count data corresponding to the certain supply voltage of the memory cell comprises:
calculating a standard deviation of the write margins;
calculating a standard deviation of the fail bit count data corresponding to a varying supply voltage of the peripheral circuit at the certain supply voltage of the memory cell; and
determining the write shift constant according to the standard deviation of the write margins and the standard deviation of the fail bit count data.

8. The method of claim 1, wherein determining the write shift ratio according to the shmoo data comprises:
determining a minimum supply voltage for a write operation according to a second boundary formed by the shmoo data;
determining a first width from an origin point of the shmoo data to a supply voltage of the memory cell across the minimum supply voltage for the write operation;
determining a second width from the origin point to a supply voltage of the peripheral circuit where the second boundary starts; and
calculating the write shift ratio according to a ratio of the first width and the second width.

9. The method of claim 8, wherein determining the minimum supply voltage for the write operation according to the second boundary is determining an intersecting point between the second boundary and a diagonal line corresponding to the supply voltage of the memory cell and the supply voltage of the peripheral circuit.

10. The method of claim 9, wherein a ratio of the supply voltage of the memory cell and the supply voltage of the peripheral circuit corresponding to each point on the diagonal line is 1.

11. The method of claim 1, wherein the write slope is independent from the read slope.

12. The method of claim 1, wherein determining the curve of the wafer according to the read slope and the write slope comprises:
determining a static noise margin mean of the wafer according to the static noise margins;
determining a minimum supply voltage for a write operation of the wafer according to the shmoo data;
determining a minimum supply voltage for a read operation of the wafer according to the shmoo data;
plotting the minimum supply voltage for the write operation corresponding to the static noise margin mean, and the minimum supply voltage for the read operation corresponding to the static noise margin mean on a graph;
plotting a write line on the graph crossing the minimum supply voltage for the write operation according to the write slope; and
plotting a read line on the graph crossing the minimum supply voltage for the read operation according to the read slope.

13. The method of claim 12, further comprising determining an optimal operating supply voltage and an optimal static noise margin.

14. The method of claim 1, wherein the shmoo data are data points used to form a first boundary and a second boundary of a shmoo plot.

15. The method of claim 1, wherein the curve is a smile curve.
